(19) United States
(12) Patent Application Publication
(10) Pub. No.: US 2022/0199926 A1
(43) Pub. Date: Jun. 23, 2022

(54) ELECTROLUMINESCENCE ELEMENT, DISPLAY DEVICE, AND METHOD FOR PRODUCING ELECTROLUMINESCENCE ELEMENT

(71) Applicant: Sharp Kabushiki Kaisha, Sakai City, Osaka (JP)

(72) Inventors: Tadashi KOBASHI, Sakai City (JP); Masaki YAMAMOTO, Sakai City (JP); Yuko OGURA, Chikushino-city (JP); Yuka TAKAMIZUMA, Chikushino-city (JP); Masanori TANAKA, Chikushino-city (JP); Soichiro NIKATA, Chikushino-city (JP); Tetsuji ITO, Chikushino-city (JP); Mayuko WATANABE, Chikushino-city (JP)

(21) Appl. No.: 17/603,559

(22) PCT Filed: Apr. 17, 2019
(86) PCT No.: PCT/JP2019/016510

§ 371 Date: Oct. 13, 2021

(51) Int. Cl. H01L 51/50; H01L 51/56; H01L 27/32; C01B 19/00; C09K 11/88

(52) U.S. Cl. CPC H01L 51/502; H01L 51/56; H01L 27/322; C01B 19/002; C09K 11/883; B82Y 20/00; H01L 2227/323; H01L 2251/305; H01L 2251/5369; H01L 2251/558; H01L 27/3244; H01L 51/5072

(57) ABSTRACT

The electroluminescent element includes a QD layer and an electron transport layer. QD phosphor particles contained in the QD layer are nanocrystals containing zinc and selenium, or zinc, selenium, and sulfur. A fluorescent half width of the QD phosphor particles is 25 nm or less, and a fluorescent peak wavelength of the QD phosphor particles is 410 nm or more and 470 nm or less. The electron transport layer contains zinc oxide. A film thickness of the electron transport layer is 15 nm or more and 85 nm or less.

### TECHNICAL FIELD

The present disclosure relates to an electroluminescent element containing quantum dot (QD) phosphor particles, and the like.

### BACKGROUND ART

In recent years, various techniques related to an electroluminescent element containing the QD phosphor particles (also referred to as semiconductor nanoparticle phosphors) have been developed. An example of the electroluminescent element is a quantum dot light emitting diode (QLED).

NPL 1 discloses an example of a manufacturing method of blue QD phosphor particles used in the QLED. The manufacturing method of NPL 1 aims to facilitate adjustment of a peak wavelength and a wavelength half width of fluorescence (blue light) emitted from blue QD phosphor particles.

### CITATION LIST

### Non Patent Literature

NPL 1: “ZnSe/ZnS quantum dots as emitting material in blue QD-LEDs with narrow emission peak and wavelength tunability”, Christian Ippen, Tonino Greco, Yohan Kim, Jiwan Kim, Min Suk Ohb, Chul Jong Han, Armin Wedel a, Organic Electronics 15 (2014), pp. 126-131

### SUMMARY OF INVENTION

### Technical Problem

An aspect of the present disclosure aims to improve performance of an electroluminescent element compared with before.

### Solution to Problem

To solve the above problem, an electroluminescent element according to an aspect of the present disclosure is an electroluminescent element including a quantum dot light-emitting layer containing quantum dots and an electron transport layer configured to transport electrons to the quantum dot light-emitting layer, wherein the quantum dots contain nanocrystals containing zinc and selenium or zinc, selenium, and sulfur, a fluorescent half width of the quantum dots is 25 nm or less, and a fluorescent peak wavelength of the quantum dots is 410 nm or more and 470 nm or less, the electron transport layer contains zinc oxide, and a film thickness of the electron transport layer is 15 nm or more and 85 nm or less.

A method for manufacturing an electroluminescent element according to an aspect of the present disclosure is a method for manufacturing an electroluminescent element including a quantum dot light-emitting layer containing quantum dots and an electron transport layer configured to transport electrons to the quantum dot light-emitting layer, the method for manufacturing an electroluminescent element including: a quantum dot synthesis step of synthesizing copper chalcogenide as a precursor from an organic copper compound or an inorganic copper compound and an organic chalcogen compound, and synthesizing the quantum dots by using the copper chalcogenide; a light-emitting layer formation step of forming the quantum dot light-emitting layer containing the quantum dots synthesized in the quantum dot synthesis step; and an electron transport layer formation step of forming the electron transport layer, wherein in the quantum dot synthesis step, the quantum dots are synthesized, the quantum dots (i) containing nanocrystals containing zinc and selenium or zinc, selenium, and sulfur, (ii) being with a fluorescent half width of 25 nm or less, and (iii) being with a fluorescent peak wavelength of 410 nm or more and 470 nm or less, and in the electron transport layer formation step, the electron transport layer is formed, the electron transport layer containing zinc oxide and having a film thickness of 15 nm or more and 85 nm or less.

### Advantageous Effects of Invention

According to an electroluminescent element and a method for manufacturing the same according to an aspect of the present disclosure, the performance of the electroluminescent element can be improved compared with before.

### BRIEF DESCRIPTION OF DRAWINGS

FIG. 1 is a diagram illustrating a schematic configuration of an electroluminescent element according to a first embodiment.

FIG. 2 is a graph illustrating a relationship between a film thickness of an electron transport layer and an external quantum efficiency.

FIG. 3 is a diagram for describing a display device according to a second embodiment.

FIG. 4 is a diagram for describing a modified example of the display device according to the second embodiment.

FIG. 5 is a diagram for describing another modified example of the display device according to the second embodiment.

FIG. 6 is a diagram for describing a display device according to a third embodiment.

FIG. 7 is a diagram for describing a modified example of the display device according to the third embodiment.

### DESCRIPTION OF EMBODIMENTS

### First Embodiment

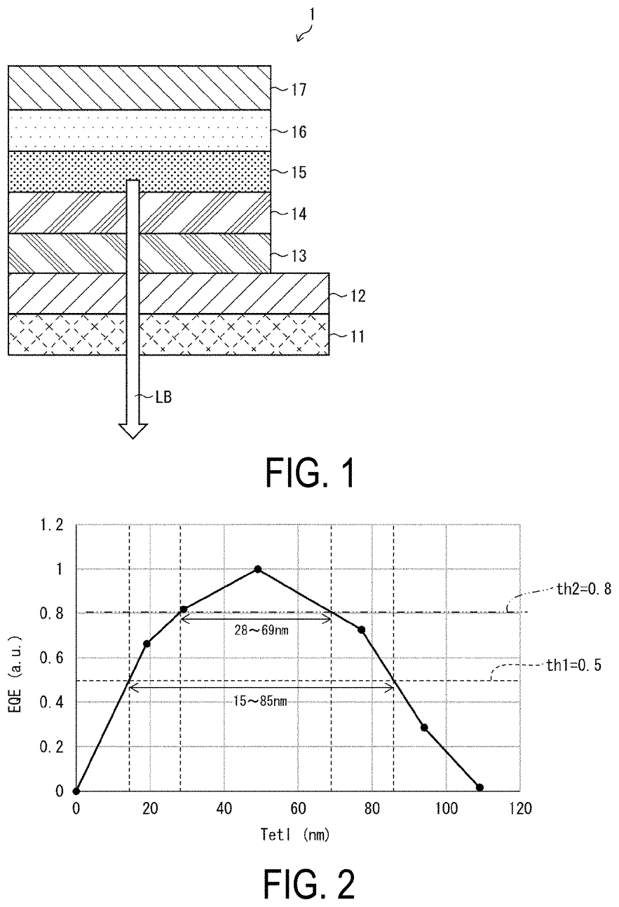

An electroluminescent element 1 according to a first embodiment will be described. Note that in the present specification, a direction from an anode electrode 12 to a cathode electrode 17 in FIG. 1 is referred to as an upward direction, and the opposite direction thereof is referred to as a downward direction. In the present specification, a horizontal direction refers to a direction perpendicular to a vertical direction (a main surface direction of each portion included in the electroluminescent element 1). The vertical direction can also be referred to as a normal direction of each portion described above.

In the present specification, a description “A to B” for two numbers A and B is intended to mean “equal to A or more and equal to B or less” unless otherwise specified.

### Example Structure of Electroluminescent Element

FIG. 1 is a diagram illustrating a schematic configuration of the electroluminescent element 1 according to the first embodiment.

The electroluminescent element 1 is an element that emits light by applying a voltage to QD phosphor particles (QD), and is, for example, a QLED. In the first embodiment, the QD phosphor particles contained in the electroluminescent element 1 are blue QD phosphor particles.

The electroluminescent element 1 includes, toward the upward direction in FIG. 1, a substrate 11, an anode electrode (an anode, a first electrode) 12, a hole injection layer (HIL) 13, a hole transport layer (HTL) 14, a QD layer 15 (quantum dot light-emitting layer, blue quantum dot light-emitting layer), an electron transport layer (ETL) 16, and a cathode electrode (a cathode, a second electrode) 17 in this order.

Thus, the QD layer 15 is interposed between the anode electrode 12 and the cathode electrode 17. In other words, the anode electrode 12 and the cathode electrode 17 are provided so as to sandwich the QD layer 15. Note that the electroluminescent element 1 may further include an electron injection layer at any position between the QD layer 15 and the cathode electrode 17.

Note that in the first embodiment, the electroluminescent element 1 is described as a bottom-emitting (bottom emission (BE)) type electroluminescent element in which blue light LB emitted from the QD layer 15 is emitted downward. In the following description, “blue light LB” is also abbreviated simply as “LB”. Other members will be similarly abbreviated as appropriate.

Note that, in FIG. 1, for simplicity of description, the electroluminescent element 1 (a blue electroluminescent element) using blue quantum dots (blue QD phosphor particles) is merely illustrated. As described below, by providing a QD layer 15 containing red quantum dots (red QD phosphor particles), an electroluminescent element emitting red light (a red electroluminescent element) can be realized. Similarly, by providing a QD layer 15 containing green quantum dots (green QD phosphor particles), an electroluminescent element emitting green light (a green electroluminescent element) can also be realized. Such a red electroluminescent element and a green electroluminescent element are also included in the technical scope of the electroluminescent element according to an aspect of the present disclosure.

The substrate 11 supports, above thereof, the anode electrode 12, the hole injection layer 13, the hole transport layer 14, the QD layer 15, the electron transport layer 16, and the cathode electrode 17. The substrate 11 is, for example, configured with a substrate having high transparency (e.g., a glass substrate). Banks may be formed on the substrate 11 so that patterning of a red pixel (an R pixel), a green pixel (a G pixel), and a blue pixel (a B pixel) can be performed.

The anode electrode 12 is an electrode to which a voltage is applied so as to supply positive holes to the QD layer 15. The anode electrode 12 is configured, for example, with a material having a relatively large work function. Examples of the material include, for example, tin doped indium oxide (ITO), zinc doped indium oxide (IZO), aluminum doped zinc oxide (AZO), gallium doped zinc oxide (GZO), and antimony doped tin oxide (ATO). The anode electrode 12 is transparent so as to transmit the LB emitted from the QD layer 15.

For example, sputtering, film evaporation, vacuum vapor deposition, or physical vapor deposition (PVD) is used for film formation of the anode electrode 12.

The hole injection layer 13 is a layer that transports positive holes supplied from the anode electrode 12, to the hole transport layer 14. The hole injection layer 13 may be formed of an organic material or may be formed of an inorganic material. An example of the organic material is an electrically conductive polymer material. As the polymer material, for example, a composite of poly(3,4-ethylenedioxythiophene):polystyrene sulfonate (PEDOT:PSS) can be used.

The hole transport layer 14 is a layer that transports positive holes supplied from the hole injection layer 13, to the QD layer 15. The hole transport layer 14 may be formed of an organic material or may be formed of an inorganic material. An example of the organic material is an electrically conductive polymer material. As the polymer material, for example, poly[(9,9-dioctylfluorenyl-2,7-diyl)-co-(4,4′-(N-(4-sec-butylphenyl) diphenylamine))] (TFB) can be used.

For example, sputtering, vacuum vapor deposition, PVD, spin coating, or ink-jet is used for film formation of the hole injection layer 13 and the hole transport layer 14. Note that in a case where positive holes can be sufficiently supplied to the QD layer 15 only by the hole transport layer 14, the hole injection layer 13 need not be provided.

The QD layer 15 is a light-emitting layer (QD phosphor particle layer) provided between the anode electrode 12 and the cathode electrode 17 and containing the QD phosphor particles.

The QD phosphor particles emit the LB accompanied by recombination of the positive holes supplied from the anode electrode 12 and the electrons (free electrons) supplied from the cathode electrode 17. In other words, the QD layer 15 emits light through electro-luminescence (EL) (more specifically, injection type EL).

In the first embodiment, each QD phosphor particle has a core/shell structure including a core and a shell coated on the surface of the core. The shell may be formed in a state of solid solution on the surface of the core. Note that the QD phosphor particle may include only the core. Even in this case, the QD phosphor particles emit the LB accompanied by the recombination of the positive holes and the electrons.

The QD phosphor particles do not contain cadmium (Cd), and zinc selenide (ZnSe) based or ZnSeS-based QD phosphor particles are used.

Specifically, the core of the QD phosphor particle is a nanocrystal (a nanoparticle having a particle diameter of about several nm to several tens nm) containing zinc (Zn) and selenium (Se), or Zn, Se, and sulfur (S). In other words, the core of the QD phosphor particle is configured with ZnSe or ZnSeS. The shell of the QD phosphor particle, similar to the core, does not contain Cd and is configured with, for example, zinc sulfide (ZnS). However, the material of the shell may be any material as long as not containing Cd. Note that the QD phosphor particle itself is also a nanocrystal.

A number of surface modifiers (organic ligands) are coordinated on the surface of the QD phosphor particles. By coordinating the surface modifiers, mutual aggregation of QD phosphor particles can be suppressed, and thus target optical characteristics are easily exhibited.

The surface modifier is, for example, a compound containing a functional group having a hetero atom. Examples of the surface modifier include a phosphine-base, an amine-base, a thiol-base, and fatty acids. In this case, at least one of these is selected as the surface modifier.

Examples of the phosphine-base include trioctylphosphine and trioctylphosphine oxide. Examples of the amine-base include octylamine, hexadecylamine, oleylamine, octadecylamine, dioctylamine, and trioctylamine. Examples of the thiol-base include dodecanethiol and hexadecanethiol. Examples of the fatty acids include lauric acid, myristic acid, palmitic acid, and stearic acid.

The QD phosphor particles are synthesized using copper chalcogenide as a precursor synthesized from an organic copper compound or an inorganic copper compound and an organic chalcogen compound. Specifically, in the QD phosphor particles, metal exchange between copper (Cu) of copper chalcogenide and Zn is performed. Safe synthesis can be performed by synthesizing the QD phosphor particles, based on an indirect synthesis reaction using such relatively stable materials (relatively low reactive materials).

The fluorescent half width of the QD phosphor particles is 25 nm or less. As described above, in a case where the QD phosphor particles are synthesized (produced) by performing indirect synthesis by using the copper chalcogenide as the precursor, the fluorescent half width of 25 nm or less can be achieved, so that high color gamut can be achieved.

Note that the fluorescent half width is a full width at half maximum (FWHM), which indicates spread of a fluorescent wavelength at half the intensity of a peak value of a fluorescence intensity in a fluorescent spectrum. In the following description, the fluorescent half width is also abbreviated simply as “half width”.

The fluorescent peak wavelength of the QD phosphor particles is 410 nm or more and 470 nm or less. Since the QD phosphor particles are the ZnSe-based or ZnSeS-based solid solution using chalcogen elements in addition to Zn, the particle diameter and composition of the QD phosphor particles can be adjusted. Thus, by adjusting the particle diameter and composition, the range of the fluorescent peak wavelength can be adjusted. Note that the fluorescent peak wavelength is preferably 430 nm or more, and more preferably 440 nm or more. Furthermore, the fluorescent peak wavelength is more preferably 460 nm or less.

Quantum yield (QY) of the QD phosphor particles (in the present specification, referred to as “fluorescence quantum yield”) is 10% or more. The QY is preferably 30% or more, and more preferably 50% or more.

Spin coating, ink-jet, or photolithography, for example, is used for film formation of the QD layer 15.

The electron transport layer 16 is a layer that transports electrons supplied from the cathode electrode 17, to the QD layer 15. The electron transport layer 16 may be formed of an organic material or may be formed of an inorganic material. In the case of the inorganic material, it is nanoparticles composed of, for example, a metal oxide containing at least one of Zn, magnesium (Mg), titanium (Ti), silicon (Si), tin (Sn), tungsten (W), tantalum (Ta), barium (Ba), zirconium (Zr), aluminum (Al), yttrium (Y), and hafnium (Hf). From the perspective of electron mobility, zinc oxide (ZnO), for example, is selected as the inorganic material. In the first embodiment, a case where ZnO is used as the material of the electron transport layer 16 is illustrated. The electron transport layer 16 is formed so as to have a film thickness of 15 nm to 85 nm.

Spin coating or ink-jet, for example, is used for the film formation of the electron transport layer 16.

The cathode electrode 17 is an electrode to which a voltage is applied so as to supply electrons to the QD layer 15. The cathode electrode 17 is a reflective electrode that reflects the LB emitted from the QD layer 15.

The cathode electrode 17 is configured, for example, with a material having a relatively small work function. Examples of the material include Al, silver (Ag), Ba, ytterbium (Yb), calcium (Ca), lithium (Li)—Al alloy, Mg—Al alloys, Mg—Ag alloys, Mg-indium (In) alloys, and Al-aluminum oxide (Al₂ O₃) alloys.

For example, sputtering, film evaporation, vacuum vapor deposition, or PVD is used for film formation of the cathode electrode 17.

In the electroluminescent element 1, a forward voltage is applied between the anode electrode 12 and the cathode electrode 17 (the anode electrode 12 is set to a potential higher than that of the cathode electrode 17), thereby making it possible to (i) supply electrons from the cathode electrode 17 to the QD layer 15 and (ii) supply positive holes from the anode electrode 12 to the QD layer 15. As a result, the QD layer 15 can generate the LB accompanied by the recombination of the positive holes and the electrons. The above-described application of the voltage may be controlled by the thin film transistor (TFT) (not illustrated). As an example, a TFT layer including a plurality of TFTs may be formed in the substrate 11.

Note that the electroluminescent element 1 may include a hole blocking layer (HBL) that suppresses the transport of the positive holes. The hole blocking layer is provided between the anode electrode 12 and the QD layer 15. By providing the hole blocking layer, the balance of the carriers (i.e., positive holes and electrons) supplied to the QD layer 15 can be adjusted.

In addition, the electroluminescent element 1 may include an electron blocking layer (EBL) that suppresses the transport of electrons. The electron blocking layer is provided between the QD layer 15 and the cathode electrode 17. By providing the electron blocking layer, the balance of the carriers (i.e., positive holes and electrons) supplied to the QD layer 15 can also be adjusted.

The electroluminescent element 1 may be sealed after the film formation up to the cathode electrode 17 is completed. For example, a glass or a plastic can be used as a sealing member. The sealing member has, for example, a concave shape so that a layered body from the substrate 11 to the cathode electrode 17 can be sealed. For example, after a sealing adhesive (e.g., an epoxy-based adhesive) is applied between the sealing member and the substrate 11, sealing is performed under a nitrogen (N₂) atmosphere, and thereby the electroluminescent element 1 is manufactured.

### Application to Display Device

The electroluminescent element 1 is, for example, applied as a blue light source of a display device. The light source including the electroluminescent element 1 may include an electroluminescent element as a red light source and an electroluminescent element as a green light source. In this case, the above-described light source functions as a light source to illuminate a red (R) pixel, a green (G) pixel, and a blue (B) pixel (see also the second embodiment below). The display device including this light source can express an image by a plurality of pixels including the R pixel, the G pixel, and the B pixel.

For example, the R pixel, the G pixel, and the B pixel are each formed by employing ink-jet or the like for separate application on the substrate 11 provided with the bank. For example, indium phosphide (InP) is suitably used as the red QD phosphor particles and the green QD phosphor particles used for the R pixel and G pixel respectively, as long as the materials are limited to non-Cd-based materials. When InP is used, the fluorescent half width can be made relatively narrow, and high luminous efficiency can be obtained.

A film formation of the electron transport layer 16 may be performed in a unit of a plurality of the pixels or may be performed in common for the plurality of pixels, provided that the display device can light up the R pixel, G pixel, and B pixel individually.

### Method for Manufacturing Electroluminescent Element

Next, an example of a method for manufacturing the electroluminescent element 1 will be described. The electroluminescent element 1 is manufactured, for example, by performing film formation of the anode electrode 12, the hole injection layer 13, the hole transport layer 14, the QD layer 15, the electron transport layer 16, and the cathode electrode 17 on the substrate 11 in this order.

Specifically, for example, the anode electrode 12 is formed on the substrate 11 by sputtering (anode electrode formation step). Next, after a solution containing, for example, PEDT:PSS is applied to the anode electrode 12 by spin coating, a solvent is volatilized by baking to form the hole injection layer 13 (hole injection layer formation step). Next, after a solution containing, for example, TFB is applied to the hole injection layer 13 by spin coating, a solvent is volatilized by baking to form the hole transport layer 14 (hole transport layer formation step). Next, after a solution in which the QD phosphor particles are dispersed is applied to the hole transport layer 14 by spin coating, a solvent is volatilized by baking to form the QD layer 15 (light-emitting layer formation step). Next, after a solution containing nanoparticles of ZnO is applied to the QD layer 15 by spin coating, a solvent is volatilized by baking to form the electron transport layer 16. Next, the cathode electrode 17 is formed on the electron transport layer 16 by vacuum vapor deposition (electron transport layer formation step). [0052]

Note that the QD phosphor particles contained in the QD layer 15 are synthesized by synthesizing copper chalcogenide as a precursor from an organic copper compound or an inorganic copper compound and an organic chalcogen compound and using the copper chalcogenide (quantum dot synthesis step). In other words, in the light-emitting layer formation step, the QD layer 15 containing the QD phosphor particles synthesized in this manner is formed. The quantum dot synthesis step (also referred to as a QD phosphor particle synthesis step) will be described later.

As described above, in the electron transport layer formation step, the electron transport layer 16 is formed so as to have a film thickness of 15 nm to 85 nm.

Note that after the film formation of the cathode electrode 17, the substrate 11 and the layered body formed on the substrate 11 (the anode electrode 12 to the cathode electrode 17) may be sealed with a sealing member under an N₂ atmosphere.

### Method for Synthesizing QD Phosphor Particles

Next, an example of a method for synthesizing the QD phosphor particles (QD phosphor particle synthesis step) will be described.

First, in the first embodiment, copper chalcogenide (precursor) is synthesized from an organic copper compound or an inorganic copper compound and an organic chalcogen compound. Specifically, copper selenide: Cu₂Se or copper sulfide selenide: Cu₂SeS can be exemplified as the precursor.

Here, in the first embodiment, the Cu raw material of Cu₂Se is not particularly limited, but for example, the following organic copper reagent or inorganic copper reagent can be used. In other words, for example, copper (I) acetate: Cu(OAc) or copper (II) acetate: Cu(OAc)₂ can be used as the acetate. As a fatty acid salt, for example, copper stearate: Cu(OC(═O)C₁₇H₃₅)₂, copper oleate: Cu(OC(═O)C₁₇H₃₃)₂, copper myristate: Cu(OC(═O)C₁₃H₂₇)₂, copper dodecanoate: Cu(OC(═O)C₁₁H₂₃)₂, or copper acetylacetonate: Cu(acac)₂ can be used. As the halide, both monovalent and divalent compounds can be used, and for example, copper (I) chloride: CuCl, copper (II) chloride: CuCl₂, copper (I) bromide: CuBr, copper (II) bromide: CuBr₂, copper (I) iodide: CuI, or copper (II) iodide: CuI₂ can be used.

In the first embodiment, an organic selenium compound (organic chalcogenide) is used as a raw material of Se. The structure of the compound is not particularly limited, but for example, trioctylphosphine selenide: (C₈H₁₇)₃P═Se in which Se is dissolved in trioctylphosphine, or tributylphosphine selenide: (C₄H₉)₃P═Se in which Se is dissolved in tributylphosphine can be used. Alternatively, a solution (Se-ODE) in which Se is dissolved at a high temperature in a high-boiling-point solvent, which is a long chain hydrocarbon such as octadecene, or a solution (Se-DDT/OLAm) in which Se is dissolved in a mixture of oleylamine and dodecanethiol, or the like can be used.

In the first embodiment, the organic copper compound or the inorganic copper compound and the organic chalcogen compound are mixed and dissolved. Octadecene as a saturated hydrocarbon or unsaturated hydrocarbon having a high-boiling-point can be used as the solvent. Alternatively, t-butylbenzen as an aromatic high-boiling-point solvent, and butyl butyrate: C₄H₉COOC₄H₉, benzilbutyrate: C₆H₅CH₂COOC₄H₉, or the like as a high-boiling-point ester based solvent can be used. However, aliphatic amine base, fatty acid based compounds, fatty phosphorus based compounds, or mixtures thereof can also be used as the solvent.

At this time, the reaction temperature is set to 140° C. to 250° C., and the copper chalcogenide (precursor) is synthesized. Note that the reaction temperature is preferably a lower temperature of 140° C. to 220° C., and more preferably a much lower temperature of 140° C. to 200° C. In this way, in the first embodiment, since the copper chalcogenide can be synthesized at a lower temperature, the copper chalcogenide can be safely synthesized. In addition, since the reaction during synthesis is gentle, the reaction is easier to control.

In the first embodiment, there is no particular limitation on the reaction method, but it is important to synthesize Cu₂Se and Cu₂SeS having uniform particle diameter in order to obtain the QD phosphor particles having a narrow half width.

In the first embodiment, in order to obtain ZnSe having a narrower half width, it is important to solid-dissolve S in the core. For this reason, in the synthesis of the precursor Cu₂Se, it is preferable to add thiol, and it is more preferable to use Se-DDT/OLAm as the Se raw material in order to obtain the QD phosphor particles having a narrower half width. Without particularly limiting the thiol, for example, octadecanethiol: C₁₈H₃₇SH, hexadecanethiol: C₁₆H₃₃SH, tetradecanethiol: C₁₄H₂₉SH, dodecanethiol: C₁₂H₂₅SH, decanethiol C₁₀H₂₁SH, or octanethiol: C₈H₁₇SH can be used as the thiol.

Next, an organozinc compound or an inorganic zinc compound is prepared as a raw material of ZnSe or ZnSeS. The organozinc compound or the inorganic zinc compound is a raw material which is stable even in the air and easy to handle. Without particularly limiting the structure of the organozinc compound or the inorganic zinc compound, a zinc compound with high ionic properties is preferably used in order to efficiently perform a reaction of metal exchange (metal exchange reaction). For example, the organozinc compound and the inorganic zinc compound described below can be used. For example, zinc acetate: Zn(OAc)₂ or zinc nitrate: Zn(NO₃)₂ can be used as the acetate. Furthermore, for example, zinc stearate: Zn(OC(═O)C₁₇H₃₅)₂, zinc oleate: Zn(OC(═O)C₁₇H₃₃)₂, zinc palmitate: Zn(OC(═O)C₁₅H₃₁)₂ zinc myristate: Zn(OC(═O)C₁₃H₂₇)₂, zinc dodecanoate: Zn(OC(═O)C₁₁H₂₃)₂, or zinc acetylacetonate: Zn(acac)₂ can be used as the fatty acid salt. For example, zinc chloride: ZnCl₂, zinc bromide: ZnBr₂, or zinc iodide: ZnI₂ can be used as the halide. Furthermore, for example, zinc diethyldithiocarbamate: Zn(SC(═S)N(C₂H₅)₂)₂, zinc dimethyldithiocarbamate: Zn(SC(═S)N(CH₃)₂)₂, or zinc dibutyldithiocarbamate: Zn(SC(═S)N(C₄H₉)₂)₂ can be used as the zinc carbamate.

Subsequently, the above-described organozinc compound or inorganic zinc compound is added to the reaction solution in which the precursor of the copper chalcogenide has been synthesized. This results in a metal exchange reaction between Cu of the copper chalcogenide and Zn. The metal exchange reaction is preferably carried out at 180° C. to 280° C. It is also more preferable that the metal exchange reaction is carried out at a lower temperature of 180° C. to 250° C. As described above, in the first embodiment, since the metal exchange reaction can be performed at a lower temperature, it is possible to increase the safety of the metal exchange reaction. Furthermore, the metal exchange reaction becomes easy to control.

In the first embodiment, it is preferable that the metal exchange reaction of Cu and Zn proceeds quantitatively and the nanocrystals do not contain the Cu of the precursor. This is because when the Cu of the precursor remains, the Cu serves as a dopant, and light is emitted by another light emission mechanism, so that the half width is widened. The residual amount of the Cu is preferably 100 ppm or less, more preferably 50 ppm or less, and ideally 10 ppm or less.

In the first embodiment, when the metal exchange is performed, a compound having an auxiliary role of liberating the metal of the precursor into the reaction solution by coordination, chelating, or the like is necessary.

An example of the compound having the above-described role is a ligand (surface modifier) capable of forming a complex with Cu. Examples thereof include a phosphorus-based (phosphine-based) ligand, an amine-based ligand, and a sulfur-based (thiol-based) ligand. Among them, in consideration of the high reaction efficiency, the phosphorus-based ligand is more preferable. As a result, the metal exchange between Cu and Zn is appropriately performed, and the QD phosphor particles having a narrow half width based on Zn and Se can be manufactured.

As described above, in the first embodiment, the copper chalcogenide is synthesized as the precursor from the organic copper compound or the inorganic copper compound and the organic chalcogen compound. The QD phosphor particles are synthesized by performing the metal exchange using the precursor. As described above, in the first embodiment, the QD phosphor particles are synthesized through the synthesis of the precursor (after synthesizing the precursor first). In other words, in the first embodiment, unlike conventional techniques (e.g., the technique of NPL 1), the QD phosphor particles are indirectly synthesized (not directly synthesized). Such indirect synthesis obviates the use of reagents which are dangerous to handle due to high reactivity. In other words, the ZnSe-based QD phosphor particles having a narrow half width can be safely and stably synthesized.

Furthermore, in the first embodiment, it is also not necessary to isolate and purify the precursor. Thus, for example, it is possible to obtain the desired QD phosphor particles by performing the metal exchange between Cu and Zn by one pot. However, in the first embodiment, the copper chalcogenide as the precursor may be isolated and purified prior to the synthesis of the QD phosphor particles.

The QD phosphor particles synthesized by the above-described technique can exhibit predetermined fluorescence characteristics without various treatments such as cleaning, isolation and purification, coating treatment, and ligand exchange. However, in order to further improve QY, it is preferable to coat the core (nanocrystal) of the QD phosphor particle with the shell.

In the first embodiment, the core/shell structure can be formed at the stage of synthesizing the precursor. For example, in a case where the shell structure is formed using ZnSe as a material, the precursor (copper chalcogenide) having the core/shell structure of Cu₂Se/Cu₂S can be synthesized. Thereafter, by performing the metal exchange between Cu and Zn, the QD phosphor particles having the core/shell structure of ZnSe/ZnS can be synthesized.

In the first embodiment, the S-based material used for the shell structure is not particularly limited. For example, a material of thiols can be used as the S-based material. Specific examples of the material of thiols include the materials described above, or benzenethiol: C₆H₅SH may be used. S-ODE or S-DDT/OLAm may be used as the S-based material.

As described above, the QD phosphor particles (i) containing the above-described nanocrystals, (ii) having a half width of 25 nm or less, and (iii) having the fluorescent peak wavelength of 410 nm or more and 470 nm or less is synthesized.

Furthermore, as described above, by synthesizing the QD phosphor particles by using the copper chalcogenide as the precursor, safe synthesis can be performed. In addition, since the reaction during synthesis is gentle, it is easy to control the growth of the QD phosphor particles.

When the reaction described above is vigorous, the growth of individual QD phosphor particles will differ due to a slight deviation in a reaction time, a temperature, and the like. In this case, since the band gap also differs due to a variation in size of individual QD phosphor particles, when the QD phosphor particles are caused to emit light, the fluorescent wavelength of the emitted light tends to be relatively broad. As described above, when it is easy to control the growth of the QD phosphor particles, since it is possible to suppress the occurrence of the above-described variation, the half width can be narrowed to 25 nm or less, and the fluorescent peak wavelength can be adjusted in the above-described range.

In the above-described synthesis method of the QD phosphor particles, the copper chalcogenide as the precursor is synthesized from the organic copper compound or the inorganic copper compound and the organic chalcogen compound. Then, by using the copper chalcogenide (specifically, by performing the metal exchange between Cu of the copper chalcogenide and Zn), the QD phosphor particles are synthesized.

Thus, as described above, safe synthesis can be performed. For example, as compared with a case where the QD phosphor particles are synthesized using a direct synthesis method using an organic zinc compound and a material having relatively high reactivity (e.g., diphenylphosphine selenide disclosed in NPL 1), safe synthesis can be performed. Since the reactivity of the raw materials for synthesizing the QD phosphor particles is relatively low, safe storage is possible. Thus, the above-described method for synthesizing the QD phosphor particles is also suitable for mass production of the QD phosphor particles.

### EXAMPLE

A description follows regarding an example. In this example, the QD phosphor particles of the ZnSeS-base (also referred to as ZnSeS-based QD phosphor particles) that do not contain Cd are synthesized (formed) as follows. By using the QD phosphor particles (quantum dots) that do not contain Cd, in other words, are composed of a non-Cd-based material, there is an effect that an environmentally friendly QD phosphor particles can be provided. Note that the following measuring apparatuses were used for the synthesis and evaluation of the QD phosphor particles, and evaluation of the electroluminescent element.

Spectrofluorometer: F-2700 manufactured by Hitachi High-Tech Science Corporation

Ultraviolet visible near-infrared spectrophotometer: V-770 manufactured by JASCO Corporation

QY measuring device: QE-1100 manufactured by Otsuka Electronics Co., Ltd.

X-ray diffraction (XRD) apparatus: D2 PHASER manufactured by Bruker Corporation

Scanning transmission electron microscope (STEM): SU9000 manufactured by Hitachi High-Tech Corporation

LED measurement apparatus: manufactured by Spectra Co-op (two-dimensional CCD small high sensitivity spectrometer Solid Lambda CCD manufactured by Carl Zeiss AG) Example of Synthesis of QD Phosphor Particles

First, a synthesis example of the QD phosphor particles will be described.

A 300 mL reaction vessel was charged with anhydrous copper acetate: Cu(OAc)₂ 543 mg, dodecanethiol: DDT 9 mL, oleylamine: OLAm 9 mL, and octadecene: ODE 57 mL. Then, the resultant was heated while being stirred under an inert gas (N₂) atmosphere to dissolve the raw materials.

Se-DDT/OLAm solution (0.3 M) 10.5 mL was added to the solution, and the resultant was heated at 220° C. for 10 minutes while being stirred. The resulting reaction solution (Cu₂SeS) was cooled to room temperature.

Zinc chloride: ZnCl₂ 4092 mg, trioctylphosphine: TOP 60 mL, and oleylamine: OLAm 2.4 mL were added to the solution, and the resultant was heated at 220° C. for 30 minutes while being stirred under an inert gas (N₂) atmosphere. The resulting reaction solution (ZnSeS) was cooled to room temperature.

Ethanol was added to the ZnSeS reaction liquid to generate precipitate, the precipitate was recovered by centrifugation, and ODE was added to the precipitate to be dispersed.

Thereafter, zinc chloride: ZnCl₂ 6150 mg, trioctylphosphine: TOP 30 mL, and oleylamine: OLAm 3 mL were added to the ZnSeS-ODE solution, and the resultant was heated at 280° C. for 60 minutes while being stirred under an inert gas (N₂) atmosphere. The resulting reaction solution (ZnSeS) was cooled to room temperature.

S-DDT/OLAm solution (0.1 M) 15 mL was added to the solution, and the resultant was heated at 220° C. for 30 minutes while being stirred. The resulting reaction solution (ZnSeS) was cooled to room temperature.

Thereafter, zinc chloride: ZnCl₂ 2052 mg, trioctylphosphine: TOP 36 mL, and oleylamine: OLAm 1.2 mL were added to the solution, and the resultant was heated at 230° C. for 60 minutes while being stirred under an inert gas (N₂) atmosphere. The resulting reaction solution (ZnSeS) was cooled to room temperature.

Dodecylamine: DDA 0.6 mL was added to the reaction solution, and the resultant was heated at 220° C. for 5 minutes while being stirred under an inert gas (N₂) atmosphere.

S-ODE solution (0.1 M) 6 mL was added to the solution, and heated at 220° C. for 10 minutes while being stirred, and further zinc octanoate solution (0.1 M) 12 mL was added and the resultant was heated at 220° C. for 10 minutes while being stirred. The heating and stirring operations of the S-ODE solution and the zinc octanoate solution were performed twice in total. Thereafter, the resultant was heated at 200° C. for 30 minutes while being stirred. The resulting reaction solution (ZnSeS—ZnS) was cooled to room temperature.

### Verification of QD Phosphor Particles

The reaction solution synthesized as described above was measured using an XRD apparatus, and the peak value of the XRD spectrum of ZnSeS proved that ZnSeS solid solution was synthesized as the QD phosphor particles.

Furthermore, the above-described reaction solution was measured using the spectrofluorometer, the half width of the QD phosphor particles was 15 nm, and the fluorescent peak wavelength was 436 nm. The QD phosphor particles was measured using the STEM, and the particle diameter of the QD phosphor particles was 6.9 nm in diameter. Note that the particle diameter was calculated from the average value of the observation samples in the particle observation using the STEM image of the QD phosphor particles.

### Manufacturing Example of Electroluminescent Element

Next, a manufacturing example of the electroluminescent element 1 using the QD phosphor particles will be described.

First, an ITO film having a film thickness of 100 nm was formed as the anode electrode 12 on the substrate 11, which was a glass substrate, by sputtering. Next, after a solution containing PEDT:PSS was applied by spin coating, a solvent was volatilized by baking to form the hole injection layer 13 (PEDOT:PSS film) having a film thickness of 40 nm. Next, after a solution containing TFB was applied by spin coating, a solvent was volatilized by baking to form the hole transport layer 14 (TFB film) having a film thickness of 40 nm. Next, after the dispersed solution in which the ZnSeS-based QD phosphor particles synthesized as described above were dispersed was applied by spin coating, a solvent was volatilized by baking to form the QD layer 15 (ZnSeS-based QD phosphor particle film) having a film thickness of 26 nm. Next, after a solution containing ZnO nanoparticles was applied by spin coating, a solvent was volatilized by baking to form the electron transport layer 16 (ZnO nanoparticle film) having a predetermined film thickness. Next, an Al film having a film thickness of 100 nm was formed as the cathode electrode 17 by vacuum vapor deposition. Next, the substrate 11 and the layered body formed on the substrate 11 were sealed with a sealing member under an N₂ atmosphere.

In the present example, in order to verify the relationship between the film thickness (Teti in FIG. 2) of the electron transport layer 16 and the performance of the electroluminescent element 1, the inventors of the present application (hereinafter, the inventors) manufactured a plurality of the electroluminescent elements 1 having different Tet1s. In the present example, six kinds of electroluminescent elements 1 were manufactured. Specifically, the following samples A to F were manufactured:

Sample A: sample of Tet1=19 nm,

Sample B: sample of Tet1=29 nm,

Sample C: sample of Tet1=49 nm,

Sample D: sample of Tet1=77 nm,

Sample E: sample of Tet1=94 nm and

Sample F: sample of Tet1=109 nm.

### Verification of Electroluminescent Element

FIG. 2 is a graph illustrating the relationship between the film thickness (Tet1) of the electron transport layer 16 and external quantum efficiency (EQE).

In this verification, a current (more precisely, current density) of 0.03 mA/cm² to 75 mA/cm² was applied to each of the six samples. Then, by applying the current, the luminance value of the LB emitted from each sample was measured using the LED measurement apparatus (spectrometer). Thereafter, the EQE for each sample was calculated based on the measured luminance.

Note that a current was applied to each sample at a plurality of current values selected within the above-described range. As a result, a plurality of luminance values was measured for each sample. In the example of FIG. 2, EQE indicating the highest numerical value among EQEs calculated based on the plurality of luminance values for a certain sample was employed as the EQE of the certain sample.

Additionally, in the example of FIG. 2, a value in which the EQE as the actual measured value was normalized based on the maximum value (in this verification, the EQE of the sample C) was employed. Specifically, in the present verification, the EQE of the sample C was taken as a reference value (i.e., EQE=1). As described above, in the vertical axis of the graph of FIG. 2, an arbitrary unit (a.u.) is set.

Here, a case where a certain threshold th 1 (first threshold) is set for the EQE will be considered. In the example of FIG. 2, the th1 is set to 50% of the maximum EQE after normalization. In other words, th1=0.5 is set. As described below, the th1 in FIG. 2 is an example of the value of the EQE required for an electroluminescent element having good light-emission characteristics.

A case where an element configuration is designed with an electroluminescent element (or a display device using the electroluminescent element) as a product will be considered. In this case, ideally the electroluminescent element is designed such that each component of the electroluminescent element is in a state of optimally functioning (hereinafter, optimal state). The optimal state may also be expressed as a state where EQE=1.

However, in practice, when the EQE is 50% or more (i.e., 0.5 or more) of the optimal state, it is considered that sufficient performance of the product can be achieved. Thus, as described above, the th1 in the example of FIG. 2 is set to 0.5.

Furthermore, when the EQE is 80% or more (i.e., 0.8 or more) of the optimal state, the performance of the product can be further enhanced, which is more preferable. Thus, the th2 (second threshold value) (described later) in the example of FIG. 2 is set to 0.8.

The EQE (value after normalization) of each sample in the example of FIG. 2 was calculated as follows:

EQE=0.663 for the sample A,

EQE=0.818 for the sample B,

EQE=1 for the sample C,

EQE=0.727 for the sample D,

EQE=0.286 for the sample E, and

EQE=0.017 for the sample F. Hereinafter, the EQE of the sample A in the example of FIG. 2 is also represented as “EQE (A)”. The EQEs for other samples are also represented in a similar manner. As described above, it was confirmed in the samples A to D that the EQEs were the th1 or more. In other words, it was confirmed in the samples E and F that the EQEs were less than the th1.

Subsequently, as illustrated in FIG. 2, the inventors linearly interpolated each adjacent sample data. For example, by linearly connecting the origin O (a point corresponding to EQE=0) to a point corresponding to the EQE (A), data between the origin O and the sample A (more precisely, functions indicating relationships between each Tet1 and each EQE between the origin O and the sample A) were interpolated. As a result of the interpolation, it was confirmed that the lower limit of the Tet1 in which the EQE was the th1 or more was 15 nm. Similarly, as a result of the linear interpolation of the data between the samples D and E, it was confirmed that the upper limit of the Tet1 in which the EQE was the th1 or more was 85 nm.

In this way, as a result of the study by the inventors for the example of FIG. 2, it was confirmed that the Tet1 in which the EQE was the th1 or more was 15 nm to 85 nm. In other words, it was newly found by the inventors that by configuring the Tet1 to be 15 nm to 85 nm, it is possible to improve the light-emission characteristics of the electroluminescent element 1. Thus, according to the electroluminescent element 1, an electroluminescent element with superior performance compared with before can be provided.

Furthermore, a case where a threshold th2 separate from the th1 is set for the EQE will be considered. The th2 is set to a value higher than the th1. In the example of FIG. 2, the th2 is set to 80% of the maximum EQE after normalization. In other words, th2=0.8 is set. As described above, the th2 in FIG. 2 is an example of the value of the EQE required for an electroluminescent element having further good light-emission characteristics.

As illustrated in FIG. 2, as a result of the linear interpolation of the data between the samples A and B, it was confirmed that the lower limit of the Tet1 in which the EQE was the th2 or more was 28 nm. Similarly, as a result of the linear interpolation of the data between the samples C and D, it was confirmed that the upper limit of the Tet1 in which the EQE was the th2 or more was 69 nm.

In this way, as a result of the further study by the inventors for the example of FIG. 2, it was confirmed that the Tet1 in which the EQE was the th2 or more was 28 nm to 69 nm. In other words, it was newly found by the inventors that by configuring the Tet1 to be 28 nm to 69 nm, it is possible to further improve the light-emission characteristics of the electroluminescent element 1.

### Modified Example

In the above description, the electroluminescent element 1 of the BE-type has been described, but this is not a limitation, and the electroluminescent element 1 may be a top emission (TE) type electroluminescent element (see also a third embodiment described below).

In a case where the electroluminescent element 1 is of the TE-type, the LB is emitted from the QD layer 15 in the upward direction of FIG. 1. Thus, a reflective electrode is used for the anode electrode 12, and a light-transmissive electrode is used for the cathode electrode 17. A substrate having low translucency (e.g., a plastic substrate) may be used as the substrate 11.

In the electroluminescent element 1 of the TE-type, there are less components (e.g., TFTs) that obstruct the path of the LB on the light-emitting face side (emission direction) of the LB than those of the electroluminescent element 1 of the BE-type. As a result, since the aperture ratio is large, the EQE can be further improved.

### Second Embodiment

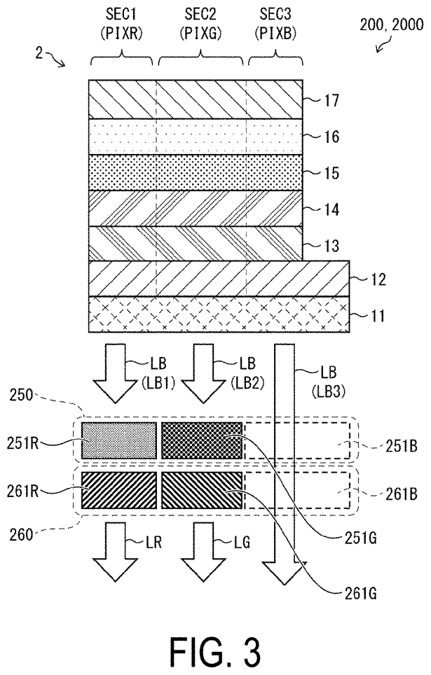

FIG. 3 is a diagram for describing a display device 2000 according to a second embodiment. The display device 2000 includes a light-emitting device 200. The light-emitting device 200 includes an electroluminescent element 2, a wavelength conversion sheet 250 (wavelength conversion member), and a color filter (CF) sheet 260 (CF member). The light-emitting device 200 may be used as a backlight for the display device 2000. The light-emitting device 200 configures one RGB pixel of the display device 2000.

The display device 2000 includes an R pixel (PIXR), a G pixel (PIXG), and a B pixel (PIXB). Note that the R pixel may be referred to as an R subpixel. This similarly applies to the G pixel and the B pixel.

The electroluminescent element 2 is a BE-type electroluminescent element similar to the electroluminescent element 1. Thus, in the example illustrated in FIG. 3, it is assumed that a display portion (not illustrated) (e.g., a display panel) of the display device 2000 is provided below the electroluminescent element 2.

In the electroluminescent element 2, the QD layer 15 (and each corresponding layer) is partitioned into three subregions (SEC1 to SEC3) in the horizontal direction. More specifically, in the electroluminescent element 2, a plurality of TFTs (not illustrated) are provided in each of the SEC1 to SEC3 so that individual voltages can be applied to the QD layer 15. Accordingly, the light emission state of the QD layer 15 can be individually controlled in each of the SEC1 to SEC3.

The LB s that are emitted from the SEC1 to SEC3 are also referred to as LB1 to LB3 below. In the example of FIG. 3, the SEC1 is set to the PIXR, the SEC2 is set to the PIXG, and the SEC3 is set to the PIXB as the respective corresponding subregions.

The wavelength conversion sheet 250 is provided below the electroluminescent element 2 at positions corresponding to the SEC1 to SEC3. The wavelength conversion sheet 250 converts a wavelength of a portion of the LB (LB1 and LB2) emitted from the QD layer 15. The wavelength conversion sheet 250 includes a red wavelength conversion layer 251R (red wavelength conversion member) and a green wavelength conversion layer 251G (green wavelength conversion member). The wavelength conversion sheet 250 further includes a blue light transmission layer 251B.

The red wavelength conversion layer 251R is provided at a position corresponding to the SEC1. In other words, the PIXR includes the red wavelength conversion layer 251R. The red wavelength conversion layer 251R includes red QD phosphor particles (not illustrated) that emit red light (LR) as fluorescence by receiving the LB1 as excitation light. In other words, the red wavelength conversion layer 251R converts the LB1 into the LR. The red wavelength conversion layer 251R may be referred to as a red quantum dot light-emitting layer.

As described above, unlike the QD layer 15, the red wavelength conversion layer 251R emits light by photo-luminescence (PL). The amount of light of the LR can be changed by adjusting the amount of light of the LB1, which is the excitation light. This similarly applies to the green wavelength conversion layer 251G described below. In the SEC1, the LR passing through the red CF 261R is emitted toward the display portion.

The green wavelength conversion layer 251G is provided at a position corresponding to the SEC2. In other words, the PIXG includes the green wavelength conversion layer 251G. The green wavelength conversion layer 251G includes green QD phosphor particles (not illustrated) that emit green light (LG) as fluorescence by receiving the LB2 as excitation light. In other words, the green wavelength conversion layer 251G converts the LB2 into the LG. The green wavelength conversion layer 251G may be referred to as a green quantum dot light-emitting layer. In the SEC2, the LG passing through the green CF 261G is emitted toward the display portion.

The blue light transmission layer 251B is provided at a position corresponding to the SEC3. The blue light transmission layer 251B transmits the LB3. The material of the blue light transmission layer 251B is not particularly limited. The material is preferably a material having a particularly high light transmittance in at least the blue wavelength band (e.g., a glass or a resin having translucency). According to the above configuration, in the SEC3, the LB3 transmitted through the blue light transmission layer 251B is emitted toward the display portion.

In the second embodiment, a blue light transmission layer (hereinafter, a blue light transmission layer 261B) similar to that of the blue light transmission layer 251B is also provided in the CF sheet 260. The blue light transmission layer 261B is also provided at a position corresponding to the SEC3. The material of the blue light transmission layer 261B may be the same as or different from the material of the blue light transmission layer 251B. In the second embodiment, the LB3 transmitted through the blue light transmission layer 251B further passes through the blue light transmission layer 261B and is directed toward the display portion.

Note that the blue light transmission layer 261B of the CF sheet 260 may be provided with a blue CF. Alternatively, in a case where the CF sheet 260 is not provided, the blue CF may be provided in the blue light transmission layer 251B of the wavelength conversion sheet 250.

As described above, according to the light-emitting device 200, light in which the LR, the LG, and the LB3 are mixed (mixed light) can be supplied to the display portion. Accordingly, by appropriately adjusting each of the amounts of light of the LR, the LG, and the LB3, the desired tinge can be represented by the above-described mixed light.

The materials of the red QD phosphor particles and the green QD phosphor particles are arbitrary. As described above, as an example, InP is suitably used as the non-Cd-based material. When InP is used, the fluorescent half width can be made relatively narrow, and high luminous efficiency can be obtained.

As described in the first embodiment, by using the QD layer 15 as the blue light source, the half width of the blue light and the fluorescent peak wavelength can be controlled precisely compared with before. In other words, the monochromaticity of the blue light (LB3) in the PIXB can be improved. In view of this, in the light-emitting device 200, the wavelength conversion sheet 250 (more specifically, the red wavelength conversion layer 251R and the green wavelength conversion layer 251G) is provided as a red light source and a green light source.

According to the red wavelength conversion layer 251R, the monochromaticity of the red light (LR) in the PIXR can be improved. Similarly, according to the green wavelength conversion layer 251G, the monochromaticity of the green light (LG) in the PIXG can be improved. Thus, according to the light-emitting device 200, the display device 2000 having excellent display quality (color reproducibility, in particular) can be realized.

However, the wavelength conversion sheet 250 cannot necessarily convert all of the LB (LB1 and LB2) received in the SEC1 and the SEC2 into light of a different wavelength. Specifically, the red wavelength conversion layer 251R cannot necessarily convert all of the LB1 into the LR. In other words, part of the LB1 is not absorbed in the red wavelength conversion layer 251R and passes through the red wavelength conversion layer 251R. Similarly, part of the LB2 is not absorbed in the green wavelength conversion layer 251G and passes through the green wavelength conversion layer 251G. Hereinafter, the LB1 passing through the red wavelength conversion layer 251R is referred to as a first residual blue light. The LB2 passing through the green wavelength conversion layer 251G is referred to as a second residual blue light.

Thus, in order to reduce the effect of the LB passing through the wavelength conversion sheet 250 in the SEC1 and SEC2 (the first residual blue light and the second residual blue light), the CF sheet 260 is provided at a position corresponding to the wavelength conversion sheet 250. The CF sheet 260 is provided below the wavelength conversion sheet 250. In other words, the CF sheet 260 is provided so as to cover the wavelength conversion sheet 250 when viewed from the display surface. The CF sheet 260 includes a red CF 261R and a green CF 261G. As described above, the CF sheet 260 further includes a blue light transmission layer 261B.

In order to reduce the effect of the first residual blue light in the PIXR, the red CF 261R is provided at a position corresponding to the SEC1 (a position corresponding to the red wavelength conversion layer 251R). Similarly, in order to reduce the effect of the second residual blue light in the PIXG, the green CF 261G is provided at a position corresponding to the SEC2 (a position corresponding to the green wavelength conversion layer 251G).

The red CF 261R and the green CF 261G selectively transmit red light and green light, respectively. Specifically, the red CF 261R has a high light transmittance in the red wavelength band and a relatively low light transmittance in other wavelength bands. The green CF 261G has a high light transmittance in the green wavelength band and a relatively low light transmittance in other wavelength bands. In the second embodiment, it is preferable that each of the red CF 261R and the green CF 261G have a particularly low light transmittance in the blue wavelength band.

By providing the CF sheet 260, the first residual blue light directed toward the display portion can be blocked by the red CF 261R. Similarly, the second residual blue light directed toward the display portion can be blocked by the green CF 261G. As a result, the monochromaticity of each of the LR and the LG in the display portion can be further improved. Thus, the display quality of the display device 2000 can be further enhanced. However, depending on the display quality required for the display device 2000, the CF sheet 260 can be omitted.

The wavelength conversion sheet 250 and the CF sheet 260 may be formed integrally. For example, by forming the CF sheet 260 on the upper face of the wavelength conversion sheet 250 at the positions corresponding to the SEC1 to SEC3, an integral sheet (hereinafter, referred to as a “wavelength conversion/CF sheet”) may be manufactured. The wavelength conversion/CF sheet may be disposed below the electroluminescent element 2 such that the CF sheet 260 side of the wavelength conversion/CF sheet faces the display surface.

As another example, by forming the wavelength conversion sheet 250 on the upper face of the CF sheet 260 at the positions corresponding to the SEC1 to SEC3, the wavelength conversion/CF sheet may be manufactured.

As yet another example, the wavelength conversion/CF sheet may be manufactured by forming the red wavelength conversion layer 251R and the green wavelength conversion layer 251G on the upper face of the CF sheet 260 at the respective positions corresponding to the SEC1 and SEC2. As described above, the wavelength conversion sheet may be provided only at positions corresponding to the SEC1 and the SEC2. In this case, the formation of the blue light transmission layer 251B can be omitted.

### Supplement

When the film thickness of the wavelength conversion sheet 250 (more specifically, the film thickness of each of the red wavelength conversion layer 251R and the green wavelength conversion layer 251G) (hereinafter, Dt) is too small (e.g., less than 0.1 μm), the absorption of the LB in the wavelength conversion sheet 250 is insufficient, so that the wavelength conversion efficiency of the wavelength conversion sheet 250 decreases. On the other hand, when the Dt is too large (e.g., when the Dt exceeds 100 μm), the light extraction efficiency in the wavelength conversion sheet 250 decreases. The decrease in the light extraction efficiency is due to, for example, the fluorescence (LR and LG) generated in the wavelength conversion sheet 250 being scattered by the wavelength conversion sheet 250 itself.

As described above, from the perspective of improving the efficiency of the light-emitting device 200, the Dt is preferably 0.1 μm to 100 μm. In order to further improve the efficiency, the Dt is particularly preferably 5 μm to 50 μm. As an example, the Dt can be set to a desired value by forming the wavelength conversion sheet 250 by using a binder.

The material of the binder is arbitrary, but an acrylic resin is preferably used as the material. This is because the acrylic resin has high transparency and can effectively disperse the QDs.

### Modified Example

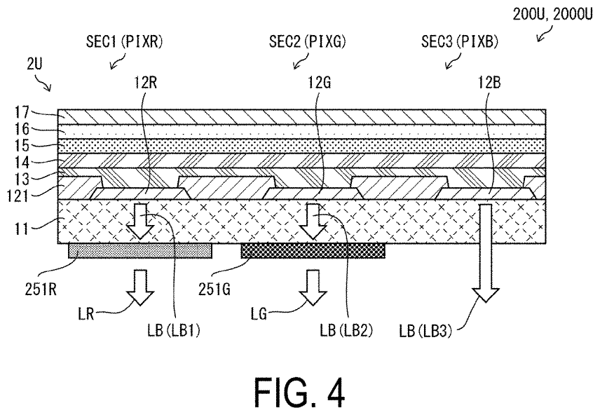

FIG. 4 is a diagram for describing one modified example of the display device 2000 (hereinafter, a display device 2000U). The light-emitting device and the electroluminescent element of the display device 2000U are referred to as a light-emitting device 200U and an electroluminescent element 2U, respectively. In FIG. 4, for simplicity of illustration, some of the members illustrated in FIG. 3 are not omitted.

In the display device 2000U, a first electrode (e.g., an anode electrode) is provided individually on the PIXR, the PIXG, and the PIXB. Hereinafter, (i) a first electrode provided on the PIXR is referred to as a red first electrode 12R, (ii) a first electrode provided on the PIXG is referred to as a green first electrode 12G, and (iii) a first electrode provided on the PIXB is referred to as a blue first electrode 12B. In the example of FIG. 4, an edge cover 121 is provided at each end of the red first electrode 12R, the green first electrode 12G, and the blue first electrode 12B.

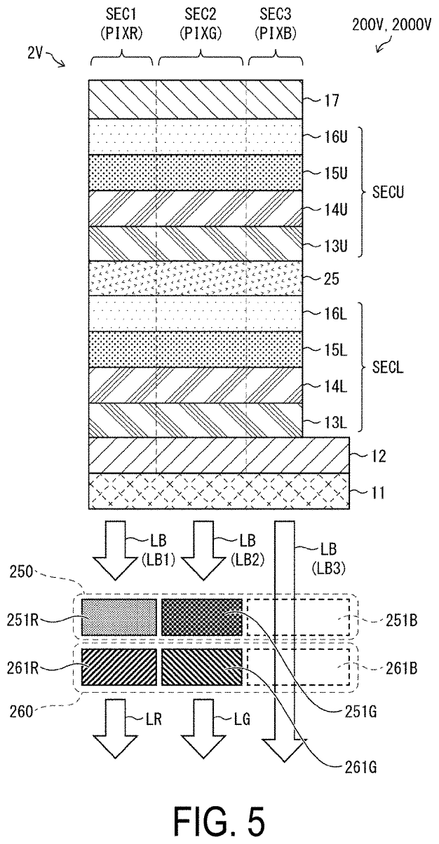

In the display device 2000U, the QD layer 15 is interposed between (i) the red first electrode 12R, the green first electrode 12G, and the blue first electrode 12B and (ii) the cathode electrode 17 (a second electrode). Additionally, the QD layer 15 is shared by the PIXR, the PIXG, and the PIXB. The cathode electrode 17 (the second electrode) is also shared by the PIXR, the PIXG, and the PIXB. This similarly applies to other layers. The display device 2000U can be said to be one specific example of the configuration of the display device 2000. The configuration of FIG. 4 is also applicable to the configurations of FIG. 5 to FIG. 7 described below.

### Modified Example

FIG. 5 is a diagram for describing another modified example of the display device 2000 (hereinafter, a display device 2000V). The light-emitting device and the electroluminescent element of the display device 2000V are referred to as a light-emitting device 200V and an electroluminescent element 2V, respectively. The electroluminescent element 2V is a tandem-type electroluminescent element configured based on the electroluminescent element 2.

Specifically, unlike the electroluminescent element 2, the electroluminescent element 2V includes a lower light-emitting unit (SECL) and an upper light-emitting unit (SECU) as a pair of light-emitting units. The SECL is formed on an upper face of the anode electrode 12. On the other hand, the SECU is formed on a lower face of the cathode electrode 17. Each of the SECL and the SECU includes layers similar to the hole injection layer 13 to the electron transport layer 16 of the electroluminescent element 2. In the example of FIG. 5, the layers of the SECL and the SECU are referred to as a hole injection layer 13L to an electron transport layer 16L, and a hole injection layer 13U to an electron transport layer 16U. In the electroluminescent element 2V, a charge generating layer 25 is further provided between the SECL and the SECU.

An example of a method for manufacturing the electroluminescent element 2V is as follows. First, after film formation of the anode electrode 12, the SECL (the hole injection layer 13L to the electron transport layer 16L) is formed on the upper face of the anode electrode 12 by similar techniques as those in the first embodiment. Then, the charge generating layer 25 is formed on the upper face of the electron transport layer 16L. Thereafter, the SECU (the hole injection layer 13U to the electron transport layer 16U) is formed on the upper face of the charge generating layer 25. Finally, the cathode electrode 17 is formed on the upper face of the electron transport layer 16U.

In the electroluminescent element 2V, two QD layers (QD layers 15L and 15U) are provided as blue light sources. Thus, according to the electroluminescent element 2V, the amount of light of the LB can be increased as compared with the electroluminescent element 2. Thus, the amounts of light of the LR and the LG can also be increased as compared with those of the electroluminescent element 2.

As described above, according to the electroluminescent element 2V, the light emission intensity of the light-emitting device 200V can be increased as compared with the light-emitting device 200. Thus, the viewability of the image displayed on the display device 2000V can be increased as compared with the display device 2000. In other words, the display device 2000V having more excellent display quality can be realized.

The charge generating layer 25 of the electroluminescent element 2V is provided as a buffer layer between the electron transport layer 16L and the hole injection layer 13U. By providing the charge generating layer 25, the efficiency of recombination of the positive holes and the electrons in the QD layers 15L and 15U can be improved. In other words, the amount of light of the LB can be increased more effectively. However, depending on the display quality required for the display device 2000V, the charge generating layer 25 can be omitted.

### Third Embodiment

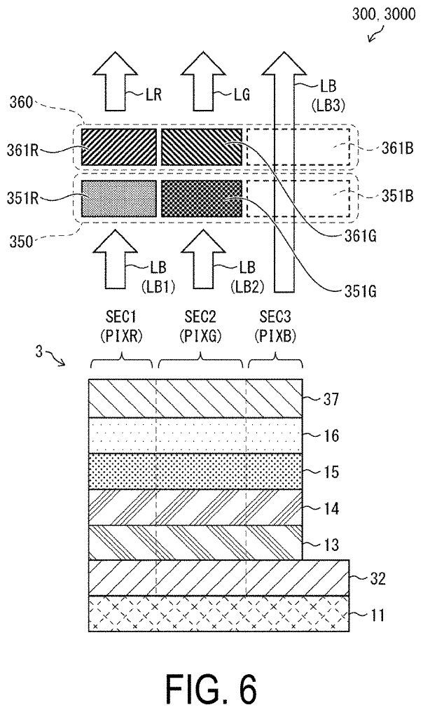

FIG. 6 is a diagram illustrating a display device 3000 according to a third embodiment. The light-emitting device and the electroluminescent element of the display device 3000 are referred to as a light-emitting device 300 and an electroluminescent element 3, respectively. The electroluminescent element 3 has a configuration generally similar to that of the electroluminescent element 2. However, unlike the electroluminescent element 2, the electroluminescent element 3 is the TE-type electroluminescent element. In the example of FIG. 6, a display portion (not illustrated) of the display device 3000 is provided above the electroluminescent element 3.

Specifically, unlike the anode electrode 12, the cathode electrode (hereinafter, the anode electrode 32) (the first electrode) of the electroluminescent element 3 is formed as a reflective electrode (an electrode similar to the cathode electrode 17). In contrast, unlike the cathode electrode 17, the cathode electrode (hereinafter, the cathode electrode 37) (the second electrode) of the electroluminescent element 3 is formed as a light-transmissive electrode (an electrode similar to the anode electrode 12). By providing the anode electrode 32 and the cathode electrode 37 in this way, the electroluminescent element 3 of the TE-type can be configured. In the electroluminescent element 3, a low transparent substrate (e.g., a plastic substrate) can be used as the substrate 11.

Each of a wavelength conversion sheet 350 and a CF sheet 360 in FIG. 6 is a wavelength conversion sheet and a CF sheet of the light-emitting device 300, respectively. A red wavelength conversion layer 351R and a green wavelength conversion layer 351G are a red wavelength conversion layer and a green wavelength conversion layer of the wavelength conversion sheet 350, respectively. A blue light transmission layer 351B is a blue light transmission layer of the wavelength conversion sheet 350. A red CF 361R and a green CF 361G are a red CF and a green CF of the CF sheet 360, respectively. A blue light transmission layer 361B is a blue light transmission layer of the CF sheet 360.

In the light-emitting device 300, since the electroluminescent element 3 is the TE-type, the wavelength conversion sheet 350 and the CF sheet 360 are disposed above the electroluminescent element 3. The third embodiment also provides similar effects as those of the second embodiment. In addition, as described above, according to the electroluminescent element 3, the EQE can be improved as compared with the electroluminescent element 2 (the BE-type electroluminescent element).

### Modified Example

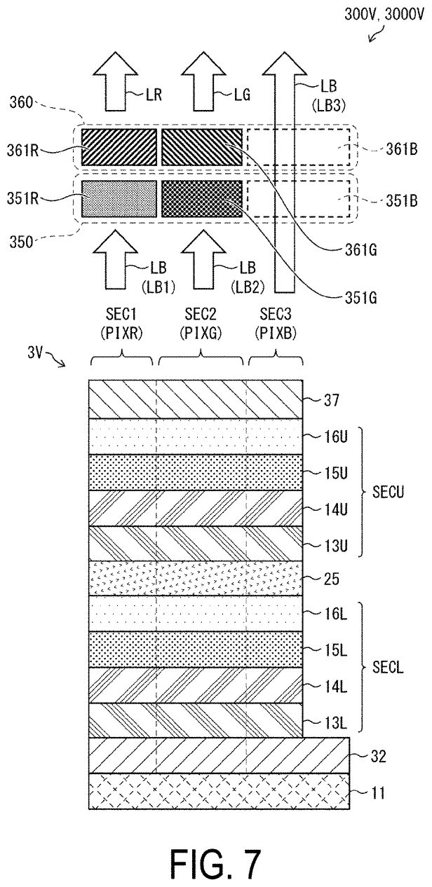

FIG. 7 is a diagram for describing one modified example of the display device 3000 (hereinafter, a display device 3000V). The light-emitting device and the electroluminescent element of the display device 3000V are referred to as a light-emitting device 300V and an electroluminescent element 3V, respectively. The electroluminescent element 3V is a tandem-type electroluminescent element configured based on the electroluminescent element 3. As described above, the tandem structure can be adopted also in the TE-type electroluminescent element in a similar manner to that in the example of FIG. 5 (the electroluminescent element 2V).

Note that in the display device described above, by using the non-Cd-based material for the red QD phosphor particles (the red quantum dots), the green QD phosphor particles (the green quantum dots), and the blue QD phosphor particles (the blue quantum dots), an effect of being possible to provide an environment-friendly display device is exerted.

### Another Expression According to Aspect of Present Disclosure

The electroluminescent element and the display device according to an aspect of the present disclosure can also be expressed as follows.

(1) An electroluminescent element according to an aspect of the present disclosure is an electroluminescent element including at least a quantum dot light-emitting layer, quantum dots of the quantum dot light-emitting layer being composed of nanocrystals containing Zn and Se, or Zn, Se, and S, and the quantum dots having a fluorescent half width of 25 nm or less and a fluorescent wavelength of 410 nm or more to 470 nm or less, an electron transport layer configured to transport electrons to the quantum dot light-emitting layer being composed of ZnO, and the electron transport layer having a film thickness of 15 nm or more and 85 nm or less.

(2) In an electroluminescent element according to one aspect of the present disclosure, the quantum dot light-emitting layer may be synthesized by synthesizing copper chalcogenide as a precursor from an organic copper compound or an inorganic copper compound and an organic chalcogen compound, and using the copper chalcogenide precursor.

(3) A display device according to an aspect of the present disclosure includes each of a wavelength conversion layer that emits red light and a wavelength conversion layer that emits green light with the electroluminescent element using the quantum dots according to (1) or (2) as excitation light.

### Additional Items

An aspect of the present disclosure is not limited to the embodiments described above, and various modifications may be made within the scope of the claims. Embodiments obtained by appropriately combining technical approaches disclosed in the different embodiments also fall within the technical scope of the aspect of the present disclosure. Moreover, novel technical features can be formed by combining the technical approaches disclosed in each of the embodiments.

### REFERENCE SIGNS LIST

1, 2, 2U, 2V, 3V Electroluminescent element
12, 32 Anode electrode (first electrode)
12R Red first electrode
12G Green first electrode
12B Blue first electrode
15, 15L, 15U QD layer (quantum dot light-emitting layer, blue quantum dot light-emitting layer)
16, 16L, 16U Electron transport layer
17, 37 Cathode electrode (second electrode)
250, 350 Wavelength conversion sheet (wavelength conversion member)
251R, 351R Red wavelength conversion layer (red wavelength conversion member)
251G, 351G Green wavelength conversion layer (green wavelength conversion member)
2000, 2000V Display device
2000U Display device
3000, 3000V Display device
Tet1 Film thickness of electron transport layer
PIXR R pixel (red pixel)
PIXG G Pixel (green pixel)
PIXB B Pixel (blue pixel)
LR Red light
LG Green light
LB, LB1 to LB3 Blue light

1. An electroluminescent element comprising:
a quantum dot light-emitting layer containing quantum dots; and
an electron transport layer configured to transport electrons to the quantum dot light-emitting layer,
wherein the quantum dots contain nanocrystals containing zinc and selenium or zinc, selenium, and sulfur,
a fluorescent half width of the quantum dots is 25 nm or less, and a fluorescent peak wavelength of the quantum dots is 410 nm or more and 470 nm or less,
the electron transport layer contains zinc oxide, and
a film thickness of the electron transport layer is 15 nm or more and 85 nm or less.

2. The electroluminescent element according to claim 1,
wherein the film thickness of the electron transport layer is 28 nm or more and 69 nm or less.

3. The electroluminescent element according to claim 1,
wherein the quantum dots are synthesized using copper chalcogenide as a precursor synthesized from an organic copper compound or an inorganic copper compound and an organic chalcogen compound.

4. The electroluminescent element according to claim 3,
wherein metal exchange between copper of the copper chalcogenide and zinc is performed in the quantum dots.

5. The electroluminescent element according to claim 4,
wherein reaction of the metal exchange is performed at a temperature of 180° C. or more and 280° C. or less.

6. The electroluminescent element according to claim 3,
wherein the copper chalcogenide is synthesized at a reaction temperature of 140° C. or more and 250° C. or less.

7. The electroluminescent element according to claim 1,
wherein the quantum dots are composed of a non-Cd-based material.

8. A display device including the electroluminescent element according to claim 1, the display device comprising:
a red pixel including a red wavelength conversion member;
a green pixel including a green wavelength conversion member; and
a blue pixel,
wherein the red wavelength conversion member includes red quantum dots configured to emit red light by receiving blue light emitted from the quantum dot light-emitting layer as excitation light, and
the green wavelength conversion member includes green quantum dots configured to emit green light by receiving the blue light as excitation light.

9. The display device according to claim 8,
wherein the red pixel includes a red first electrode,
the green pixel includes a green first electrode,
the blue pixel includes a blue first electrode,
the display device further includes a second electrode,
in the display device, the quantum dot light-emitting layer is interposed between (i) the red first electrode, the green first electrode, and the blue first electrode and (ii) the second electrode, and
the quantum dot light-emitting layer and the second electrode are shared by the red pixel, the green pixel, and the blue pixel.

10. The display device according to claim 8,
wherein the quantum dots, the red quantum dots, and the green quantum dots are composed of a non-Cd-based material.

11. A method for manufacturing an electroluminescent element including a quantum dot light-emitting layer containing quantum dots and an electron transport layer configured to transport electrons to the quantum dot light-emitting layer, the method for manufacturing an electroluminescent element comprising:
a quantum dot synthesis step of synthesizing copper chalcogenide as a precursor from an organic copper compound or an inorganic copper compound and an organic chalcogen compound, and synthesizing the quantum dots by using the copper chalcogenide;
a light-emitting layer formation step of forming the quantum dot light-emitting layer containing the quantum dots synthesized in the quantum dot synthesis step; and
an electron transport layer formation step of forming the electron transport layer,
wherein in the quantum dot synthesis step, the quantum dots are synthesized, the quantum dots (i) containing nanocrystals containing zinc and selenium or zinc, selenium, and sulfur, (ii) being with a fluorescent half width of 25 nm or less, and (iii) being with a fluorescent peak wavelength of 410 nm or more and 470 nm or less, and
in the electron transport layer formation step, the electron transport layer is formed, the electron transport layer containing zinc oxide and having a film thickness of 15 nm or more and 85 nm or less.

12. The method for manufacturing an electroluminescent element according to claim 11,
wherein in the quantum dot synthesis step, by performing metal exchange between copper of the copper chalcogenide and zinc, the quantum dots are synthesized.

13. The method for manufacturing an electroluminescent element according to claim 12,
wherein the metal exchange reaction is performed at a temperature of 180° C. or more and 280° C. or less.

14. The method for manufacturing an electroluminescent element according to claim 11,
wherein the copper chalcogenide is synthesized at a reaction temperature of 140° C. or more and 250° C. or less.
